(19) United States
(12) Patent Application Publication
(10) Pub. No.: US 2004/0213312 A1
(43) Pub. Date: Oct. 28, 2004

(54) Semiconductor laser having improved high-frequency, large signal response at reduced operating current

(76) Inventors: Michael R. Tan, Menlo Park, CA (US); David Wayne Dolfi, Los Altos, CA (US); Michael Howard Leary, Mountain View, CA (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/423,503

(22) Filed: Apr. 25, 2003

(51) Int. Cl. H01S 5/00

(52) U.S. Cl. 372/46

(57) ABSTRACT

A laser, a p-spacer, an n-spacer, and an active region is disclosed. The p-spacer has a p-doped region and an undoped region, and the n-spacer has an n-doped region and an undoped region. The active region is located between the undoped regions of the p-spacer and the n-spacer. The active region generates light of wavelength λ through the recombination of holes and electrons. The undoped region of the p-spacer has a thickness that is different from that of the undoped region of the n-spacer. In one embodiment, the p-spacer has a thickness greater than the n-spacer. If the laser is a VCSEL, the p-spacer and the n-spacer form an optical cavity having a thickness L_{c}=(n+1)λ/2, n is an integer greater than 2. In another embodiment, the cavity has a standing electromagnetic wave and wherein the active layer is located at a maximum of the standing electromagnetic wave.

### FIELD OF THE INVENTION

The present invention relates to semiconductor lasers.

### BACKGROUND OF THE INVENTION

The ever-increasing bandwidth-distance requirements of communication systems have resulted in data being transmitted over optical fibers. Both conventional telecommunications and data networks such as the Internet utilize optical fibers for both short and long distance transmission. Optical communication channels provide data rates in excess of 10 Gbits/sec at relatively modest costs. Data that is to be sent down such channels is typically generated in the form of electrical signals that are converted to optical signals by directly modulating a laser at one end of an optical fiber.

Vertical Cavity Surface Emitting Lasers (VCSELs) have become commercially important as transmitters in high bit rate (>1 Gb/s) optical communication links. In such links, the VCSEL is modulated in a large signal regime with a digital bit pattern, and therefore, the VCSEL's properties greatly affect the fidelity of the conversion of the electrical bit pattern to an optical pattern. Consider a VCSEL that is modulated by an electrical signal consisting of a step function that switches from 0 to some predetermined value in a very short period of time. Ideally, the output of the laser will be a light signal that switches from an intensity of 0 to some predetermined intensity value in a similar period of time. Unfortunately, at very high switching speeds the output of the laser has a slowly decreasing ringing pattern that is superimposed on the step function. The frequency of oscillation of the ringing pattern is related to the relaxation frequency of the laser, which is determined by the electrical-optical resonance frequency or relaxation frequency of the laser cavity. The internal damping of the cavity determines the rate at which this ringing dies out.

A similar ringing phenomenon occurs when the laser is turned off by transitions from one to zero in the modulating signal. At high modulation frequencies, the ringing in the light intensity can introduce data errors at the receiver. Hence, reducing the effects of this ringing is an important consideration in laser design and modulation protocols.

One prior method for reducing the effect of the ringing, and hence, increasing the modulation frequency, is based on the observation that both the damping factor and the relaxation frequency increases as the power level or bias current increases. The goal of such schemes is to move the relaxation frequency to a value well above the modulation frequency and to damp the oscillations as quickly as possible. If the relaxation frequency is sufficiently above the modulation frequency, the laser can follow the drive signal without a large amount of ringing. A suitable low pass filter can remove any residual low level ringing. Similarly, if the damping factor is increased, the amplitude and duration of the ringing will be reduced. Hence, by increasing the power through the VCSEL, the effects of the ringing can be reduced.

Unfortunately, the operating lifetime of the VCSEL is related to the power level at which the VCSEL is driven. For example, the failure rate of a VCSEL increases as the third power of the current density in the device. That is, doubling the current density increases the failure rate by a factor of 8. Hence, this method of reducing the effects of the ringing also substantially shortens the lifetime of the VCSEL. Also, the higher bias current increases the electrical power consumption of the data communication transceiver.

### SUMMARY OF THE INVENTION

That present invention includes a laser, a p-spacer, an n-spacer, and an active region. The p-spacer has a p-doped region and an undoped region, and the n-spacer has an n-doped region and an undoped region. The active region is located between the undoped regions of the p-spacer and the n-spacer. The active region generates light of wavelength λ through the recombination of holes and electrons. The undoped region of the p-spacer has a thickness that is different from that of the undoped region of the n-spacer. In one embodiment, the p-spacer has a thickness greater than the n-spacer. If the laser is a VCSEL, the p-spacer and the n-spacer form an optical cavity having a thickness L_{c}=(n+1)λ/2, n is an integer greater than 2. In another embodiment, the cavity has a standing electromagnetic wave and wherein the active layer is located at a maximum of the standing electromagnetic wave.

### BRIEF DESCRIPTION OF THE DRAWINGS

FIG. 1 illustrates the layers in a typical VCSEL 10 according to one embodiment of the present invention.

FIG. 2 is a magnified view of the active region shown in FIG. 1.

FIG. 3 illustrates the light output of a typical prior art VCSEL when driven by a step function that increases from zero to a fixed value at t=0.

FIG. 4 illustrates the doping patterns in the region of the laser cavity in a typical VCSEL.

FIG. 5 illustrates the doping patterns in the region of the laser cavity in a VCSEL according to another embodiment of the present invention.

FIG. 6 illustrates the basic structure of an edge-emitting laser according to another embodiment of the present invention.

FIG. 7 illustrates the doping patterns in the region of the laser cavity in an edge-emitting laser according to another embodiment of the present invention.

### DETAILED DESCRIPTION OF THE PREFERRED EMBODIMENTS OF THE INVENTION

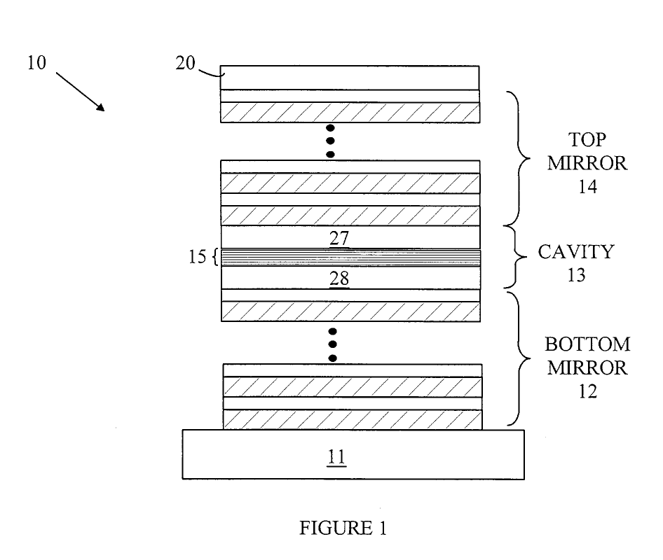

The manner in which the present invention provides its advantages can be more easily understood with reference to FIG. 1, which illustrates the layers in a typical VCSEL 10 according to one embodiment of the present invention. To simplify the drawing, the thicknesses of the various layers are not shown to scale. VCSEL 10 is constructed on a substrate 11, which, in the present embodiment, includes any contact layers needed to supply power to the bottom side of the active region. VCSEL 10 includes a bottom mirror 12, an optical cavity 13, and a top mirror 14. Power is supplied via a top contact layer 20. The mirrors are conventional DBR mirrors, and hence, will not be described in detail here. For the purposes of the present discussion it is sufficient to note that the mirrors are constructed by growing alternating layers of material in which the adjacent layers have different indices of refraction. Typically, the bottom mirror is constructed from n-type materials, and the top mirror is constructed from p-type materials. However, other designs can be utilized without departing from the teachings of the present invention.

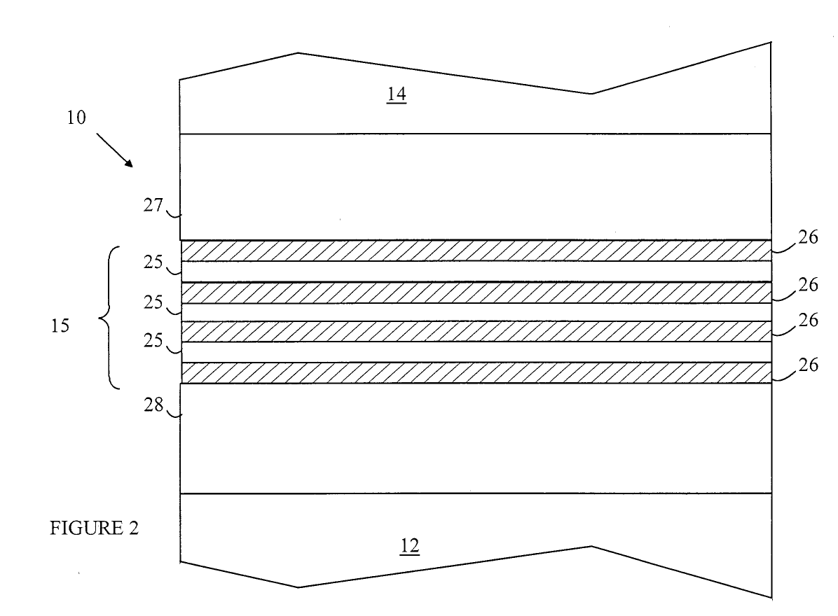

The laser cavity includes an active region 15, which is shown in greater detail in FIG. 2, which is a magnified view of the active region shown in FIG. 1. The active region is constructed from quantum well layers 25 separated by barrier layers 26. The spacer layers shown at 27 and 28 are used to set the cavity length to the desired length for the wavelength of light being generated and to position the active region at the peak of the standing wave in the cavity formed between the top and bottom mirrors. The layers and the ordering of the layers in the present invention are similar to that utilized in prior art VCSELs. However, as will be explained in more detail below, the thickness and points at which the doping begins and ends is altered in the present invention. In prior art VCSELs, the spacer layers typically have a thickness that is set such that the combined thickness of the two spacer layers and the active region is equal to λ, where λ is the wavelength of the emitted light in the materials of the optical cavity. Since the thickness of the active region is small compared to λ, the spacer layers are approximately λ/2 in prior art devices. In a VCSEL, the active region is positioned at the peak of the optical standing wave in the cavity.

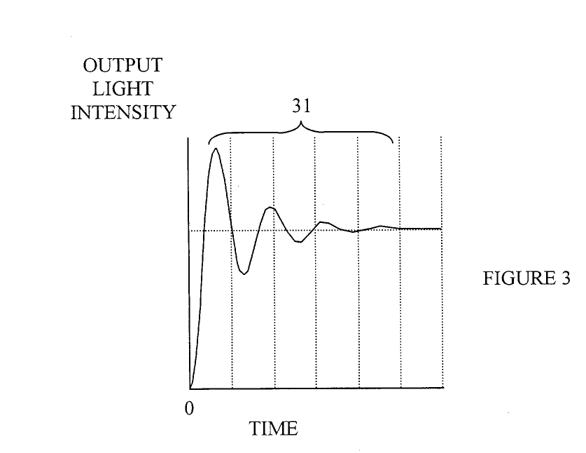

Refer now to FIG. 3, which illustrates the light output of a typical prior art VCSEL when driven by a step function that increases from zero to a fixed value at t=0. As can be seen from the drawing, the output of the laser rings for approximately the period of time shown in region 31 of the graph. If the amplitude of the ringing causes the signal to decrease below half the light level corresponding to a logical 1, the receiver at the other end of the fiber may mistake the ring for a transition from 1 to 0.

The present invention is based on the observation that introducing a delay in the time required for the holes or the electrons to reach the active region reduces the amplitude of the ringing without requiring a change in the power level at which the device is driven. The mirrors in the VCSEL are typically doped, while the spacer regions in prior art VCSELs are lightly doped with the doping ending a few tenths of nm away from the active region. When a potential is applied across the mirrors, holes are injected into the spacer that is adjacent to the p-doped mirror, and electrons are injected into the spacer that is adjacent to the n-doped mirror. The holes and electrons travel to the active region where the holes and electrons combine to generate light. In prior art VCSELs, the doping terminates close (i.e., a few tens of nm) to the active region to minimize the time it takes the carriers to reach the quantum wells.

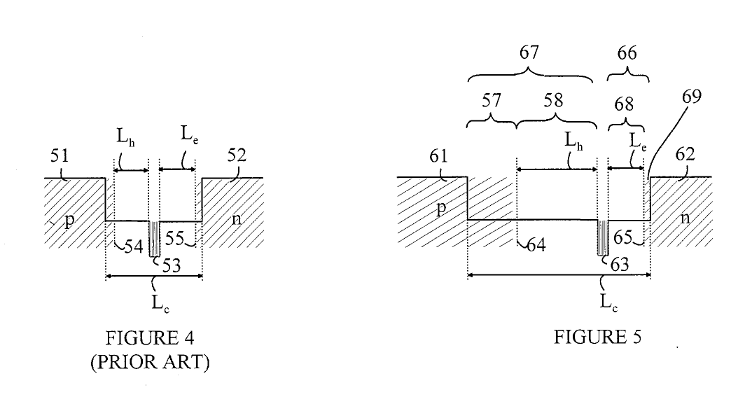

In the operation of a laser, a fixed DC current bias is applied to the laser and a modulated AC bias is superimposed. The change in AC current produces a change in the electron and hole concentrations in the spacer layers, which takes time to travel to the active region where the holes and electrons eventually recombine. This time delay affects the modulation response of the laser. Refer now to FIG. 4, which illustrates the doping patterns in the region of the laser cavity in a typical VCSEL. The mirrors that are shown at 51 and 52 define the cavity. Mirror 51 is doped with a p-type material, and mirror 52 is doped with an n-type material. The distance between the mirrors, L_{c} is normally set to be 1λ, where λ is the wavelength of the light generated by the VCSEL. However, embodiments in which L_{c} is equal to (n+1)λ/2, where n is an integer greater than 1 are also known to the art. In general, the p-doped and n-doped regions terminate in the spacer region as shown at 54 and 55. The holes generated in the p-doped region must then diffuse through an undoped region of length Lₕ in the spacer that is adjacent to the p-doped mirror before being captured by the quantum well layers shown at 53. Similarly, the electrons leaving the n-doped region of spacer 55 must diffuse through an undoped region of length Lₑ of the spacer adjacent to the n-doped mirror. The undoped regions have doping concentrations of less than 5×10¹⁷ cm⁻³. In prior art VCSELs, Lₕ and Lₑ are less than 25 nm so as to reduce the diffusion time. In typical III-V semiconductors, the electron diffusion time is 5 times less than the hole diffusion time.

The present invention is based on the observation that the damping factor is related to the time needed for the electron and holes to diffuse through these undoped regions. If this delay is increased, it can be shown that the damping factor also increases. In particular, it can be shown that the delay through the spacer regions acts in a manner analogous to a parasitic RC time constant in an electrical circuit.

It can be shown that the delay in question is given by

$$τ = \frac{{L}_{h}^{2}}{4 {D}_{h}} + \frac{{L}_{e}^{2}}{4 {D}_{e}}$$

where Lₕ is the distance the holes need to diffuse to reach the quantum wells and Lₑ is the distance the electrons need to diffuse to reach the quantum wells. Dₕ and Dₑ are the hole and electron diffusion coefficients. Dₕ is on the order of 4 cm²/sec while Dₑ is on the order of 20 cm²/sec. Hence, the preferred embodiment of the invention operates by increasing the distance through which the holes diffuse in the spacer layer on the hole side of the active layer, since a small increase in this distance provides the greatest increase in the delay or capture time.

Refer now to FIG. 5, which illustrates the doping patterns in the region of the laser cavity in a VCSEL according to the present invention. The cavity is defined by the mirrors that are shown at 61 and 62. Mirror 61 is doped with a p-type material, and mirror 62 is doped with an n-type material. The distance between the mirrors, L_{c} is set to be (n+1)λ/2, where λ is the wavelength of the light generated by the VCSEL in the cavity material. In the preferred embodiment of the invention, n>2. The p-type doping ends at location 64 in the p-type spacer 67, which has a doped region 57 and an undoped region 58. The undoped region provides a distance Lₕ for the holes to diffuse before reaching the quantum well layers shown at 63. Likewise, the n-type spacer 66 includes an undoped region 68 and a doped region 69. The n-type doping ends at location 65 in the n-type spacer leaving a distance Lₑ for the electrons to diffuse before entering the quantum well layers. In one preferred embodiment of the present invention, the thickness of the p-spacer layer is chosen to be greater than λ/2, and the thickness of the n-spacer layer is chosen to be <λ/2. The thickness of the undoped region (Lₕ) in the p-spacer layer is chosen to be greater than 20 nm, and the thickness of the undoped region in the n-spacer layer (Lₑ) is chosen to be less than 40 nm.

The exact values of Lₕ and Lₑ are determined by the desired relaxation frequency and degree of damping needed. The relaxation frequency must be higher than the modulation frequency. The relaxation frequency is set by the current flowing through the device. Hence, once the modulation frequency is set, a suitable relaxation frequency is determined by conventional means. For the purposes of the present discussion, it is sufficient to note that the relaxation frequency is determined by the differential gain of the active region, the optical mode volume, and the bias current. This, in turn, defines the current density that must flow through the device. As noted above, the lower current densities are preferred to improve the lifetime of the device. Hence, the target value for the relaxation frequency is set as low as possible to provide the lowest bias and modulation current consistent with the decoding circuitry that must decode the modulated signal after transmission.

Once the current density is set, Lₕ is varied while holding Lₑ constant, to find the value that provides the optimum damping at that current density. Typically, this is done experimentally since the amount of damping required is strongly dependent on the material properties of the quantum wells and the optical losses in the laser cavity.

The region between the top and bottom mirrors forms a cavity having a standing electromagnetic wave when current is flowing through the laser. This active layer of the laser is normally positioned such that the quantum well layers are located at a maximum of this standing wave. In a conventional VCSEL, there is one such maximum at the center of the cavity and one such maximum at each of the mirror/spacer boundaries. In a VCSEL according to the present invention, there may be a number of additional maxima in the cavity. If only the p-spacer is expanded, these additional maxima will be on the p-spacer side of the quantum wells. However, the quantum wells are still preferably positioned at the maximum of the standing wave that is closest to the n-type mirror.

The above-described embodiments of the present invention use an expanded undoped region in the p-type spacer. However, as pointed out above, the goal of increasing the delay time between the injection of the carriers into the undoped spacer region and the capture of the carriers by the quantum wells can be accomplished by increasing the thickness of the undoped region in the n-type spacer. The approach taken above is preferred, however, because the increase in thickness needed in the n-type spacer to produce a given increase in the delay time is typically 5 times greater than that needed to produce the delay using the p-type spacer.

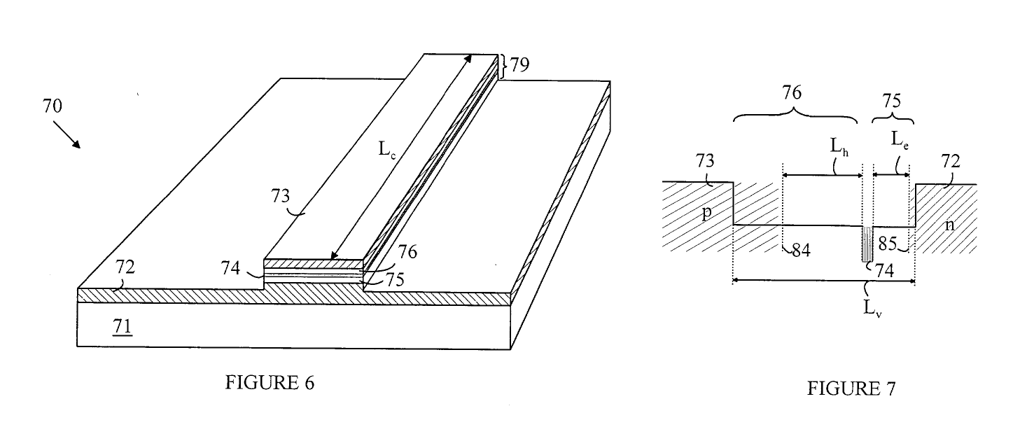

The method of the present invention can also be applied to an edge-emitting laser. The manner in which the present invention is utilized in an edge-emitting laser can be more easily understood with reference to FIG. 6, which illustrates the basic structure of an edge-emitting laser 70. Since edge-emitting lasers are well known in the art, the detailed structure of laser 70 will not be discussed here. For the purposes of the present discussion, it is sufficient to note that laser 70 is a p-i-n diode structure that is deposited on a substrate 71. Typically a number of layers are deposited on the substrate to form an n-region 72, a spacer region 75, an active region 74 having one or more quantum well layers, a second spacer region 76, and a p-region 73. The multi-layer structure is then etched to form a ridge 79 or a buried structure that acts as a wave-guide. The resonant frequency is set by the distance, L_{c}, between the ends of the ridge structure, which is cleaved to form mirrors.

The distance between the edge of the p-region and the edge of the n-region is determined by the requirement that the waveguide must support only one optical mode in the vertical direction. Since the thickness of the two spacer regions and the active region is less than one wavelength, and since the p-spacer is thicker than the n-spacer, the active region cannot always be placed exactly at a maximum of the electric field in the cavity. However, the active region can be placed close enough to the electric field maximum to allow the laser to operate satisfactorily.

In an edge-emitting laser according to the present invention, the distance between the active region and the terminus of the p-doping is adjusted to introduce damping in a manner similar to that discussed above. Refer now to FIG. 7, which illustrates the doping patterns in the region of the laser cavity in edge-emitting laser 70. Denote the vertical distance through the spacer regions and the active region by Lᵥ. The doping of the p-region 73 may continue into spacer region 76 to point 84. Similarly, the doping of the n-region 72 may continue into spacer region 75 to point 85.

The above-described embodiments of the present invention utilize a conventional p-i-n laser diode structure. However, the present invention can also be practiced in laser structures that utilize a reverse-biased tunnel junction. In a laser of this type, both the top and bottom contact layers are n-type. The laser typically has an active layer constructed on a bottom n-type contact layer. An n-p reverse-biased tunnel diode junction is deposited on the p-type spacer of the active region with the p-layer of the junction in contact with the p-doped region of the p-spacer. The top mirror and top contact are then constructed from n-type layers. This type of structure reduces the current spreading and resistivity problems associated with the p-type contact layers used in conventional lasers. Light emitting devices of this type are taught in U.S. patent application Ser. No. 09/586,406, filed Jun. 2, 2000, which is hereby incorporated by reference.

Various modifications to the present invention will become apparent to those skilled in the art from the foregoing description and accompanying drawings. Accordingly, the present invention is to be limited solely by the scope of the following claims.

What is claimed is:

1. A laser comprising:
a p-spacer having a p-doped region and an undoped region;
an n-spacer having an n-doped region and an undoped region; and
an active region between said undoped regions of said p-spacer and said n-spacer, said active region generating light of wavelength λ through the recombination of holes and electrons, wherein said undoped region of said p-spacer has a thickness that is different from that of said undoped region of said n-spacer.

2. The laser of claim 1 wherein
said p-spacer has a thickness greater than said n-spacer.

3. The laser of claim 1 wherein said p-spacer and said n-spacer form an optical cavity having a thickness L_{c}=(n+1)λ/2, n being an integer greater than 2.

4. The laser of claim 1 wherein said undoped region of said p-spacer has a thickness greater than 20 nm.

5. The laser of claim 1 wherein said undoped region in said n-spacer has a thickness less than 40 nm.

6. The laser of claim 1 wherein said cavity has a standing electromagnetic wave and wherein said active layer is located at a maximum of said standing electromagnetic wave.
